(19) United States
(12) Patent Application Publication
(10) Pub. No.: US 2026/0165011 A1
(43) Pub. Date: Jun. 11, 2026

(54) ORGANIC LIGHT EMITTING DISPLAY DEVICE

(71) Applicant: LG Display Co., Ltd., Seoul (KR)

(72) Inventors: Ji-Seok YANG, Paju-si (KR); Je-Beom PARK, Paju-si (KR); Dong-Ryul JUNG, Paju-si (KR)

(73) Assignee: LG Display Co., Ltd., Seoul (KR)

(21) Appl. No.: 19/288,338

(22) Filed: Aug. 1, 2025

(30) Foreign Application Priority Data
Dec. 11, 2024 (KR) 10-2024-0183775

(51) Int. Cl. H10K 59/80; H10K 59/122

(52) U.S. Cl. CPC H10K 59/8792; H10K 59/122

(57) ABSTRACT

An organic light emitting display device can include a substrate having an emission area and a non-emission area, a light emitting diode corresponding to the emission area and disposed on the substrate, a light-blocking bank corresponding to the non-emission area and disposed at a side of the light emitting diode, an insulating layer disposed on the light emitting diode and the light-blocking bank, and a black matrix corresponding to the non-emission area and disposed on the insulating layer. A first surface of the light-blocking bank and a first surface of the black matrix face to each other, and at least one of the first surface of the light-blocking bank and the first surface of the black matrix has a curved shape.

### CROSS-REFERENCE TO RELATED APPLICATIONS

The present application claims priority to Korean Patent Application No. 10-2024-0183775, filed in the Republic of Korea on Dec. 11, 2024, which is hereby expressly incorporated by reference in its entirety.

### BACKGROUND

### Field

The present disclosure relates to a display device, and more specifically, to an organic light emitting display device being capable of minimizing or preventing an ambient light reflection.

### Discussion of the Related Art

As the large-area display device is developed, the demand for the flat display device with small space occupancy is increasing. As one type of the flat display device, the technology of an organic light emitting display device including an organic light emitting diode (OLED), which uses an organic light emitting material, is developing rapidly.

The organic light emitting display device may not require a polarizer. However, in the organic light emitting display device without a polarizer, a limitation of display quality degradation due to an ambient (or external) light reflection can occur. Therefore, in order to minimize ambient light reflection, the organic light emitting display device can include a polarizer on the display surface. In the organic light emitting display device with the polarizer, the ambient light reflection can be minimized, but a limitation of brightness degradation can occur due to the polarizer.

### SUMMARY OF THE DISCLOSURE

The present disclosure is directed to an organic light emitting display device that substantially obviates one or more of the problems associated with the limitations and disadvantages of the related conventional art.

An object of the present disclosure is to provide an organic light emitting display device being capable of minimizing or preventing an ambient light reflection.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure provides an organic light emitting display device comprising a substrate including an emission area and a non-emission area; a light emitting diode corresponding to the emission area and disposed on the substrate; a light-blocking bank corresponding to the non-emission area and disposed at a side of the light emitting diode; an insulating layer disposed on the light emitting diode and the light-blocking bank; and a black matrix corresponding to the non-emission area and disposed on the insulating layer, wherein a first surface of the light-blocking bank and a first surface of the black matrix face to each other, and at least one of the first surface of the light-blocking bank and the first surface of the black matrix has a curved shape

Another aspect of the present disclosure provides an organic light emitting display device comprising a substrate including an emission area and a non-emission area; a light emitting diode corresponding to the emission area and disposed on the substrate; a light-blocking bank corresponding to the non-emission area and disposed at a side of the light emitting diode; an insulating layer disposed on the light emitting diode and the light-blocking bank; and a black matrix corresponding to the non-emission area and disposed on the insulating layer, wherein a first surface of the light-blocking bank and a first surface of the black matrix face to each other, and at least one of the first surface of the light-blocking bank and the first surface of the black matrix has a flat center portion and an inclined side portion extending from the flat center portion.

It is to be understood that both the foregoing general description and the following detailed description are examples and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic circuit diagram of an organic light emitting display device according to an example embodiment of the present disclosure.

FIG. 2 is a schematic cross-section view of an organic light emitting display device according to a first example embodiment of the present disclosure.

FIG. 3 is a schematic cross-section view illustrating a light path in the organic light emitting display device in FIG. 2.

FIG. 4 is a schematic cross-section view of an organic light emitting display device according to a second example embodiment of the present disclosure.

FIG. 5 is a schematic cross-section view of an organic light emitting display device according to a third example embodiment of the present disclosure.

FIG. 6 is a schematic cross-section view of an organic light emitting display device according to a fourth example embodiment of the present disclosure.

FIG. 7 is a schematic cross-section view of an organic light emitting display device according to a fifth example embodiment of the present disclosure.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described.

The expression “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present invention, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

The area, length, or thickness of each component described in the specification is illustrated for convenience of explanation, and the present invention is not necessarily limited to the area and thickness of the illustrated component.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure. Further, the term “can” fully encompasses all the meanings and coverages of the term “may” and vice versa.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Reference will now be made in detail to some of the examples and embodiments of the present disclosure, which are illustrated in the accompanying drawings. All the components of each display device/apparatus according to all embodiments of the present disclosure are operatively coupled and configured.

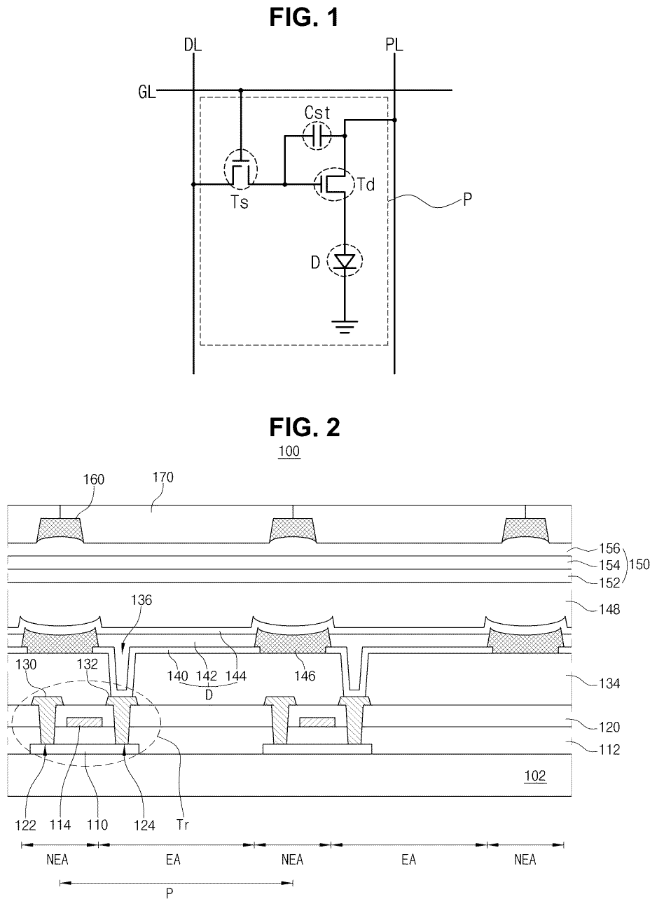

FIG. 1 is a schematic circuit diagram of an organic light emitting display device according to an example embodiment of the present disclosure.

Referring to FIG. 1, the organic light emitting display device includes a plurality of pixel regions P defined by a plurality of gate lines GL, a plurality of data lines DL and a plurality of power lines PL crossing each other. Here, one of the gate lines GL, one of the data lines DL and one of the power lines PL cross each other to define each pixel region P. In the pixel region P, a switching thin film transistor TFT Ts, a driving TFT Td, a storage capacitor Cst and an organic light emitting diode/device(OLED) D are disposed.

The pixel region can include a red pixel region, a green pixel region and a blue pixel region, but it is not limited thereto.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale. The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame. As a result, the organic light emitting display device displays a desired image.

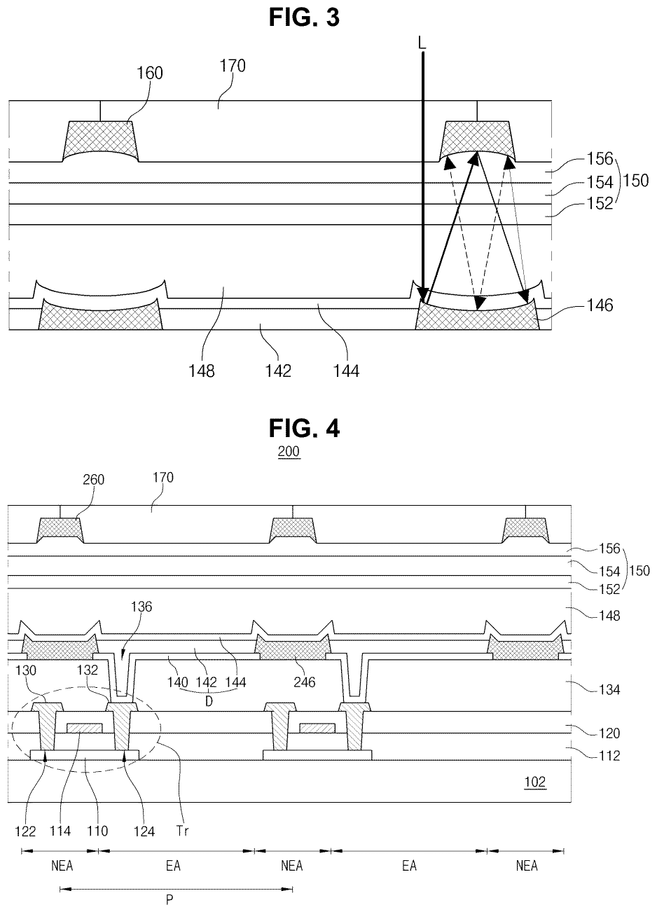

FIG. 2 is a schematic cross-section view of an organic light emitting display device according to a first example embodiment of the present disclosure, and FIG. 3 is a schematic cross-section view illustrating a light path in the organic light emitting display device in FIG. 2. Particularly, FIG. 3 is an enlarged view of a portion in FIG. 2 and shows a light path of an ambient light L incident to the organic light emitting display device. The organic light emitting display device will be explained with FIGS. 2 and 3. In all these figures, one or more pixels or pixel regions among all the pixels of the organic light emitting display device may be shown for the sake of brevity.

Referring to FIGS. 2 and 3, an organic light emitting display device 100 can include a substrate 102, a TFT Tr disposed over the substrate 102 and a first planarization layer 134 disposed over the substrate 102 and covering the TFT Tr. In addition, the organic light emitting display device 100 can include an organic light emitting diode (OLED) D connected to the TFT Tr. Moreover, the organic light emitting display device 100 can include a light-blocking bank (e.g., a light-shielding bank) 146 disposed adjacent to the OLED D, a second planarization layer 148 covering the OLED D and the light-blocking bank 146, a black matrix 160 over the second planarization layer 148 and a color control pattern 170 over the second planarization layer 148.

The pixel region P can include a plurality of pixel regions. For example, the pixel region P can include a red pixel region, a green pixel region and a blue pixel region. In addition, the pixel region P can further include a white pixel region. The pixel region P can include an emission area EA and a non-emission area NEA being adjacent to or surrounding the emission area EA.

The substrate 102 can be a glass substrate, a flexible substrate or a polymer substrate, but it is not limited thereto. For example, the substrate 102 can be one of a polyimide (PI) substrate, a polyethersulfone (PES) substrate, a polyethylenenaphthalate (PEN) substrate, a polyethylene terephthalate (PET) substrate and a polycarbonate (PC) substrate.

The TFT Tr is formed on the substrate 102. The TFT Tr can include a semiconductor layer 110, a gate electrode 114, a source electrode 130 and a drain electrode 132. In the TFT Tr, the gate electrode 114, the source electrode 130 and the drain electrode 132 are disposed over the semiconductor layer 110. Namely, the TFT Tr has a coplanar structure, but it is not limited thereto.

The semiconductor layer 110 is disposed on the substrate 102. For example, the semiconductor layer 110 can include an oxide semiconductor material. When the semiconductor layer 110 includes the oxide semiconductor material, a light-shielding pattern can be formed under the semiconductor layer 110. The semiconductor layer 120 can include a polycrystalline silicon. Impurities can be doped into both sides of the semiconductor layer 120.

A gate insulating layer 112 is formed on the semiconductor layer 110. The gate insulating layer 112 can be formed of an inorganic insulating material such as silicon oxide (SiOx) or silicon nitride (SiNx), but it is not limited thereto. (0<x≤2)

A gate electrode 114, which is formed of a conductive material, e.g., metal, is formed on the gate insulating layer 112. The gate electrode 114 can correspond to a center of the semiconductor layer 110. For example, the gate electrode 114 can be formed of a metal, e.g., copper (Cu), molybdenum (Mo), titanium (Ti), aluminum (Al), gold (Au) or silver (Ag), but it is not limited thereto. The gate electrode 114 can have a single-layered structure or a multi-layered structure.

An interlayer insulating layer 120 can be disposed on the gate electrode 114 and over an entire surface of the substrate 102. The interlayer insulating layer 120 can be formed of an inorganic insulating material, e.g., silicon oxide (SiOx) or silicon nitride (SiNx), or an organic insulating material, e.g., benzocyclobutene or photo-acryl, but it is not limited thereto. (0<x≤2)

The interlayer insulating layer 120 includes first and second contact holes 122 and 124 exposing portions of the semiconductor layer 120. The first and second contact holes 122 and 124 are positioned at both sides of the gate electrode 114 to be spaced apart from the gate electrode 114.

A source electrode 130 and a drain electrode 132 can be disposed on the interlayer insulating layer 132. The source electrode 130 and the drain electrode 132 are spaced apart from each other with respect to the gate electrode 114 and respectively contact both sides of the semiconductor layer 110 through the first and second contact holes 122 and 124.

Each of the source electrode 130 and the drain electrode 132 can be formed of a conductive material, e.g., metal. For example, each of the source electrode 130 and the drain electrode 132 can be formed of a metal, e.g., Cu, Mo, Ti, Al, Au or Ag, but it is not limited thereto. Each of the source electrode 130 and the drain electrode 132 can have a single-layered structure or a multi-layered structure.

A first planarization layer 134 is formed on an entire surface of the substrate 102 to cover the source and drain electrodes 130 and 132. Namely, the first planarization layer 134 covers the TFT Tr.

The first planarization layer 134 provides a flat top surface and has a drain contact hole 136 exposing the drain electrode 132 of the TFT Tr. The first planarization layer 134 can be formed of an inorganic insulating material, e.g., silicon oxide (SiOx) or silicon nitride (SiNx), or an organic insulating material, e.g., benzocyclobutene or photo-acryl, but it is not limited thereto. (0<x≤2)

The OLED D is disposed on the first planarization layer 134 and includes a first electrode 140, which is connected to the drain electrode 132 of the TFT Tr, an organic light emitting layer142 on the first electrode 140 and a second electrode 144 on the organic light emitting layer142. The organic light emitting layer142 and the second electrode 144 are sequentially stacked on the first electrode 140. For example, the OLED D is positioned in each of the red, green and blue pixel regions and respectively emits the red, green and blue light.

The first electrode 140 is separately formed in each pixel region. The first electrode 140 can be an anode and can include a transparent conductive oxide material layer, which can be formed of a conductive material, e.g., a transparent conductive oxide (TCO), having a relatively high work function. For example, the transparent conductive oxide material layer can be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO), but it is not limited thereto.

The first electrode 140 can have a single-layered structure of the transparent conductive oxide material layer. Namely, the first electrode 140 can be a transparent electrode. Alternatively, the first electrode 140 can further include a reflective layer to have a double-layered structure or a triple-layered structure. Namely, the first electrode 140 can be a reflective electrode.

The light-blocking bank 146 can be disposed on the first planarization layer 134. The light-blocking bank 146 can cover an edge of the first electrode 140 and be disposed to correspond to the non-emission area NEA. Namely, the light-blocking bank 146 is positioned at a boundary of the pixel region and exposes a center of the first electrode 140 in the pixel region P. The light-blocking bank 146 can include a black pigment and a photo-sensitive polymer, but it is not limited thereto. As a result, the light-blocking bank 146 can block or absorb an ambient light.

The organic light emitting layer142 including an organic emitting material is formed on the first electrode 140. For example, the organic light emitting layer142 can have a multi-layered structure including a plurality of layers.

The second electrode 144 is formed over the substrate 102 where the organic light emitting layer142 is formed. The second electrode 144 covers an entire surface of the display area and can be formed of a conductive material having a relatively low work function to serve as a cathode. For example, the second electrode 144 can be formed of aluminum (Al), magnesium (Mg), calcium (Ca), silver (Ag) or their alloy, e.g., Mg—Ag alloy (Mg:Ag). The second electrode 144 has a thin profile to have a light transparent (or semi-transparent) property.

A second planarization layer 148 can be disposed on the second electrode 144. The second planarization layer 148 can provide a flat top surface. The second planarization layer 148 can be formed of an inorganic insulating material, e.g., silicon oxide (SiOx) or silicon nitride (SiNx), or an organic insulating material, e.g., benzocyclobutene or photo-acryl, but it is not limited thereto. (0<x≤2)

An encapsulation layer (or an encapsulation film) 150 is disposed on the second planarization layer 148 to prevent penetration of moisture into the OLED D. The encapsulation layer 150 includes a first inorganic insulating layer 152, an organic insulating layer 154 and a second inorganic insulating layer 156 sequentially stacked, but it is not limited thereto.

The black matrix 160 can be disposed on the encapsulation layer 150 and correspond to the non-emission area NEA. The black matrix 160 has an opening in correspondence to the OLED D. For example, the black matrix 160 can include a material, e.g., a black resin or a carbon black, being capable of blocking or absorbing the incident light. For example, the black matrix 160 can include a black pigment and a photo-sensitive polymer, but it is not limited thereto. As a result, the black matrix can block and/or absorb the ambient light.

The black matrix 160 and the light-blocking bank 146 in the non-emission area NEA face each other. Namely, a lower surface of the black matrix 160 and an upper surface of the light-blocking bank 146 face each other. In this instance, at least one of a surface of the black matrix 160 and a surface of the light-blocking bank 146 has a curved shape. For example, at least one of the lower surface of the black matrix 160 and the upper surface of the light-blocking bank 146 has a curved shape. In an aspect of the present disclosure, both the lower surface of the black matrix 160 and the upper surface of the light-blocking bank 146 can have a curved shape. For example, each of the black matrix 160 and the light-blocking bank 146 can include a surface having a curved shape.

In an embodiment of the present disclosure, a center of the light-blocking bank 146 and a center of the black matrix 160 can be spaced apart from each other by a first distance, and an edge of the light-blocking bank 146 and an edge of the black matrix 160 can be spaced apart from each other by a second distance being smaller than the first distance.

A thickness of a side (or an edge) of the black matrix 160 can be greater than that of a center of the black matrix 160. Namely, in the black matrix 160, a thickness can be increased from the center to the side. For example, in the black matrix 160, a thickness can gradually increase from the center to the side. As a result, a surface of the black matrix 160 can have a concaved-curved shape.

A thickness of a side (or an edge) of the light-blocking bank 146 can be greater than that of a center of the light-blocking bank 146. Namely, in the light-blocking bank 146, a thickness can be increased from the center to the side. For example, in the light-blocking bank 146, a thickness can be gradually increased from the center to the side. As a result, a surface of the light-blocking bank 146 can have a concaved-curved shape.

For example, the light-blocking bank 146 can have a flat lower surface and a concaved-curved upper surface. The black matrix 160 can have a concaved-curved lower surface and a flat upper surface. Namely, the light-blocking bank 146 and the black matrix 160 can be disposed so that the curved surface of the light-blocking bank 146 and the curved surface of the black matrix 160 are face to each other.

In other word, the organic light emitting display device 100 of the present disclosure includes a first light-blocking pattern or a first light-shielding pattern (e.g., the light-blocking bank 146) having a concaved-curved upper surface and disposed in the non-emission area (NEA) and a second light-blocking pattern or a second light-shielding pattern (e.g., the black matrix 160) having a concaved-curved lower surface and disposed in the non-emission area (NEA), and the second light-blocking pattern is disposed over the first light-blocking pattern.

Referring to FIG. 3, an ambient light L being a light from outside of the organic light emitting display device 100 can be incident to a display surface. A part of the incident ambient light L can be absorbed and/or reflected by the black matrix 160.

The ambient light L, which is not absorbed and/or reflected by the black matrix 160, can reach the light-blocking bank 146. A part of the ambient light L to the light-blocking bank 146 can be absorbed and/or reflected by the light-blocking bank 146. In this instance, the ambient light L incident to a surface of the light-blocking bank 146 can be reflected by the concaved-curved surface of the light-blocking bank 146 toward the black matrix 160.

The ambient light L, which is reflected by the light-blocking bank 146 and incident to the black matrix 160, can be re-absorbed and/or re-reflected by the black matrix 160. In this instance, the ambient light L incident to the black matrix 160 can be re-reflected by the concaved-curved surface of the black matrix 160 toward the light-blocking bank 146. As a result, the ambient light L incident to the display surface of the organic light emitting display device 100 is repeatedly re-absorbed and/or re-reflected by the surface of the light-blocking bank 146 and the surface of the black matrix 160 so that the light absorption by the light-blocking bank 146 and the black matrix 160 can be maximized.

In the organic light emitting display device 100 of the present disclosure, by arranging the black matrix 160 and the light-blocking bank 146 each having a concave-curved surface, the reflection of the ambient light L incident on the organic light emitting display device 100 can be minimized. Accordingly, the organic light emitting display device 100 can minimize stains caused by the reflection of the ambient light L. As a result, the decrease of the brightness of the organic light emitting display device 100 caused by the reflection of the ambient light L can be minimized, and the degradation of the display quality of the organic light emitting display device 100 can be minimized.

For example, the black matrix 160 and the light-blocking bank 146 can include the same material, but it is not limited thereto.

A side of the light-blocking bank 146 can further extend into the emission area EA than a side of the black matrix 160. In this instance, a curved portion of the light-blocking bank 146 can protrude toward the emission area EA. The curved portion of the light-blocking bank 146 can protrude into the emission area EA beyond the black matrix 160.

Namely, the side of the light-blocking bank 146 protruding toward the emission area EA and covering an end of the first electrode 140 can be disposed closer to the emission area EA than a side of the black matrix 160 adjacent to the emission area EA where the color control pattern 170 is disposed. In other words, a side of the light-blocking bank 146 at the emission area EA side can be further extended toward the emission area EA by a protruding length compared to a side of the black matrix 160 at the emission area EA side. Accordingly, the light-blocking bank 146 can have an increased light absorption and/or reflection area. As a result, the ambient light L incident on the organic light emitting display device 100 can be absorbed and/or reflected by the light-blocking bank 146.

A width of the light-blocking bank 146 can be greater than that of the black matrix 160. Namely, the light-blocking bank 146 can have a first opening corresponding to the emission area EA, and the black matrix 160 can have a second opening, which is larger than the first opening, corresponding to the emission area EA.

Accordingly, the ambient light L reaching the protruding portion of the light-blocking bank 146 can be reflected by the concave-curved surface of the light-blocking bank 146 toward the surface of the black matrix 160. Namely, the ambient light L reflected by the surface of the light-blocking bank 146 and the black matrix 160 can be guided to the corresponding surface so that re-absorption and/or re-reflection can be repeated.

Accordingly, the reflection of the ambient light L incident on the organic light emitting display device 100 can be minimized, and the re-absorption of the ambient light L can be maximized. Accordingly, the stains of the organic light emitting display device 100 caused by the reflection of the ambient light L can be minimized. Accordingly, the brightness decrease of the organic light emitting display device 100 caused by the reflection of the ambient light L can be minimized, and the display quality degradation of the organic light emitting display device 100 can be minimized.

The color control pattern 170 can be a color filter pattern or a color conversion pattern. The color control pattern 170 can be disposed in the opening, which corresponds to the OLED D, of the black matrix 160. A part of the color control pattern 170 can overlap the black matrix 160 and can be disposed on the encapsulation layer 150. The color control pattern 170 can correspond to the emission area EA and can be alternately arranged with the black matrix 160.

For example, when the pixel region P includes the red, green and blue pixel regions, the color control pattern 170 can include a red color filter pattern corresponding to the red pixel region, a green color filter pattern corresponding to the green pixel region and a blue color filter pattern corresponding to the blue pixel region.

FIG. 4 is a schematic cross-section view of an organic light emitting display device according to a second example embodiment of the present disclosure. The organic light emitting display device 200 of FIG. 4 is different from the organic light emitting display device 100 of FIG. 2 only in the structure of a light-blocking bank 246 and a black matrix 260, and the other structures are the same. The description to the other structures is omitted or may be briefly provided.

Referring to FIG. 4, the black matrix 260 in the non-emission area NEA and the light-blocking bank 246 in the non-emission area NEA face each other. Namely, a lower surface of the black matrix 260 and an upper surface of the light-blocking bank 246 face each other. At least one of a surface of the black matrix 260 and a surface of the light-blocking bank 246 includes a flat center portion and an inclined portion extending from the flat center portion. For example, the surface of the black matrix 260 can include a flat center portion and an inclined portion extending from the flat center portion. For example, the surface of the light-blocking bank 246 can include a flat center portion and an inclined portion extending from the flat center portion.

A thickness of a side (or an edge) of the black matrix 260 can be greater than that of a center of the black matrix 260. Namely, in the black matrix 260, the center portion can have a constant thickness, and the inclined portion can be thicker toward the end of the black matrix 260. Namely, the black matrix 260 can have a sloped surface with the inclined portion in one side direction.

A thickness of a side (or an edge) of the light-blocking bank 246 can be greater than that of a center of the light-blocking bank 246. Namely, in the light-blocking bank 246, the center portion can have a constant thickness, and the inclined portion can be thicker toward the end of the light-blocking bank 246. Namely, the light-blocking bank 246 can have a sloped surface with the inclined portion in one side direction.

For example, a lower surface of the light-blocking bank 246 can flat, and an upper surface of the light-blocking bank 246 can include a flat center portion and an inclined side portion. An upper surface of the black matrix 260 can flat, and a lower surface of the black matrix 260 can include a flat center portion and an inclined side portion.

A side of the light-blocking bank 246 can further extend into the emission area EA than a side of the black matrix 260. In this instance, an inclined side portion of the light-blocking bank 246 can protrude toward the emission area EA. Namely, the side of the light-blocking bank 246 protruding toward the emission area EA and covering an end of the first electrode 140 can be disposed closer to the emission area EA than a side of the black matrix 260 adjacent to the emission area EA where the color control pattern 170 is disposed. In other words, a side of the light-blocking bank 246 at the emission area EA side can be further extended toward the emission area EA by a protruding length compared to a side of the black matrix 260 at the emission area EA side. Accordingly, the light-blocking bank 246 can have an increased light absorption and/or reflection area. As a result, the ambient light L incident on the organic light emitting display device 200 can be absorbed and/or reflected by the light-blocking bank 246.

A width of the light-blocking bank 246 can be greater than that of the black matrix 260. The inclined side portion of the black matrix 260 can be disposed to face the inclined side portion of the light-blocking bank 246. The ambient light L incident to the inclined side portion of the light-blocking bank 246 is lead toward the black matrix 260 and can be reflected by the inclined portion toward the black matrix 260.

The ambient light L, which is reflected by the light-blocking bank 246 and incident to the black matrix 260, can be reflected by the inclined portion toward the light-blocking bank 246. Namely, the ambient light L reflected by the surface of the light-blocking bank 246 and the black matrix 260 can be guided to the corresponding surface, and re-absorption and/or re-reflection can be repeated. Accordingly, the reflection of the ambient light L incident on the organic light emitting display device 200 can be minimized, and the re-absorption of the ambient light L can be maximized. As a result, in the organic light emitting display device 200, the stains caused by the reflection of the ambient light L can be minimized. Therefore, the brightness decrease of the organic light emitting display device 200 caused by the reflection of the ambient light L can be minimized, and the display quality degradation of the organic light emitting display device 200 can be minimized.

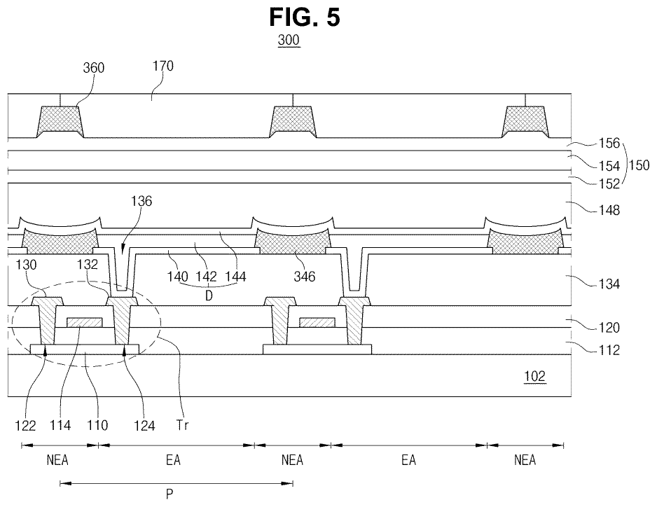

FIG. 5 is a schematic cross-section view of an organic light emitting display device according to a third example embodiment of the present disclosure. The organic light emitting display device 300 of FIG. 5 is different from the organic light emitting display device 100 of FIG. 2 only in the structure of a black matrix 360, and the other structures are the same. The description to the other structures is omitted or may be briefly provided.

Referring to FIG. 5, the black matrix 360 in the non-emission area NEA and the light-blocking bank 346 in the non-emission area NEA face each other. Namely, a lower surface of the black matrix 360 and an upper surface of the light-blocking bank 346 face each other. A surface of the black matrix 360 can include a flat center portion and an inclined portion extending from the flat center portion. A surface of the light-blocking bank 346 can be a curved shape.

A thickness of a side (or an edge) of the black matrix 360 can be greater than that of a center of the black matrix 360. Namely, in the black matrix 360, the center portion can have a constant thickness, and the inclined portion can be thicker toward the end of the black matrix 360. Namely, the black matrix 360 can have a sloped surface with the inclined portion in one side direction.

A thickness of a side (or an edge) of the light-blocking bank 346 can be greater than that of a center of the light-blocking bank 346. Namely, in the light-blocking bank 346, a thickness can be increased from a center to an edge. The light-blocking bank 346 can have a curved concave shape.

For example, a lower surface of the light-blocking bank 346 can flat, and an upper surface of the light-blocking bank 346 can have a curved concave shape. An upper surface of the black matrix 360 can flat, and a lower surface of the black matrix 360 can include a flat center portion and an inclined side portion.

A side of the light-blocking bank 346 can further extend into the emission area EA than a side of the black matrix 360. In this instance, an end of the curved surface of the light-blocking bank 346 can protrude toward the emission area EA. Namely, the side of the light-blocking bank 346 protruding toward the emission area EA and covering an end of the first electrode 140 can be disposed closer to the emission area EA than a side of the black matrix 360 adjacent to the emission area EA where the color control pattern 170 is disposed. In other words, a side of the light-blocking bank 346 at the emission area EA side can be further extended toward the emission area EA by a protruding length compared to a side of the black matrix 360 at the emission area EA side. Accordingly, the light-blocking bank 346 can have an increased light absorption and/or reflection area. As a result, the ambient light L incident on the organic light emitting display device 300 can be absorbed and/or reflected by the light-blocking bank 346.

A width of the light-blocking bank 346 can be greater than that of the black matrix 360. The inclined side portion of the black matrix 360 can be disposed to face the concaved curved surface of the light-blocking bank 346. The ambient light L incident to the concaved curved surface of the light-blocking bank 346 is lead toward the black matrix 360 and can be reflected by the black matrix 360.

The ambient light L, which is reflected by the light-blocking bank 346 and incident to the black matrix 360, can be reflected by the inclined side portion toward the concaved curved surface of the light-blocking bank 346. Namely, the ambient light L reflected by the surface of the light-blocking bank 346 and the black matrix 360 can be guided to the corresponding surface, and re-absorption and/or re-reflection can be repeated. Accordingly, the reflection of the ambient light L incident on the organic light emitting display device 300 can be minimized, and the re-absorption of the ambient light L can be maximized. As a result, in the organic light emitting display device 300, the stains caused by the reflection of the ambient light L can be minimized. Therefore, the brightness decrease of the organic light emitting display device 300 caused by the reflection of the ambient light L can be minimized, and the display quality degradation of the organic light emitting display device 300 can be minimized.

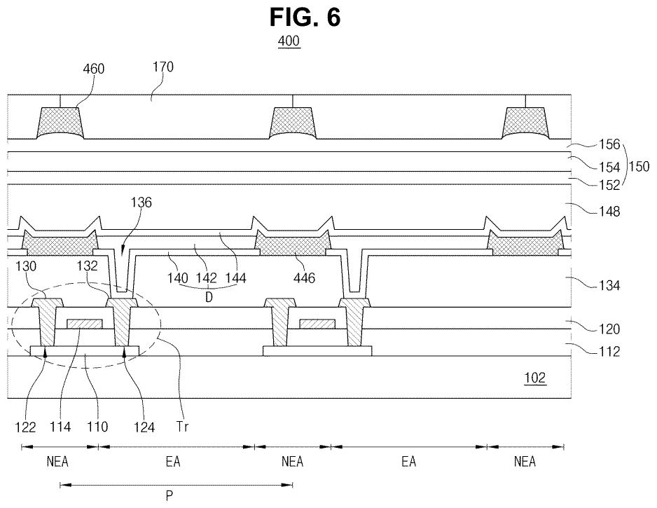

FIG. 6 is a schematic cross-section view of an organic light emitting display device according to a fourth example embodiment of the present disclosure. The organic light emitting display device 400 of FIG. 6 is different from the organic light emitting display device 100 of FIG. 2 only in the structure of a light-blocking bank 446, and the other structures are the same. The description to the other structures is omitted or may be briefly provided.

Referring to FIG. 6, the black matrix 460 in the non-emission area NEA and the light-blocking bank 446 in the non-emission area NEA face each other. Namely, a lower surface of the black matrix 460 and an upper surface of the light-blocking bank 446 face each other. A surface of the light-blocking bank 446 can include a flat center portion and an inclined portion extending from the flat center portion. A surface of the black matrix 460 can be a curved shape.

A thickness of a side (or an edge) of the light-blocking bank 446 can be greater than that of a center of the light-blocking bank 446. Namely, in the light-blocking bank 446, the center portion can have a constant thickness, and the inclined portion can be thicker toward the end of the light-blocking bank 446. Namely, the light-blocking bank 446 can have a sloped surface with the inclined portion in one side direction.

A thickness of a side (or an edge) of the black matrix 460 can be greater than that of a center of the black matrix 460. Namely, in the black matrix 460, a thickness can be increased from a center to an edge. The black matrix 460 can have a curved concave shape.

For example, a lower surface of the light-blocking bank 446 can flat, and an upper surface of the light-blocking bank 446 can include a flat center portion and an inclined side portion. An upper surface of the black matrix 460 can flat, and a lower surface of the black matrix 460 can have a curved concave shape.

A side of the light-blocking bank 446 can further extend into the emission area EA than a side of the black matrix 460. In this instance, an inclined side portion of the light-blocking bank 446 can protrude toward the emission area EA. Namely, the side of the light-blocking bank 446 protruding toward the emission area EA and covering an end of the first electrode 140 can be disposed closer to the emission area EA than a side of the black matrix 460 adjacent to the emission area EA where the color control pattern 170 is disposed. In other words, a side of the light-blocking bank 446 at the emission area EA side can be further extended toward the emission area EA by a protruding length compared to a side of the black matrix 460 at the emission area EA side. Accordingly, the light-blocking bank 446 can have an increased light absorption and/or reflection area. As a result, the ambient light L incident on the organic light emitting display device 400 can be absorbed and/or reflected by the light-blocking bank 446.

A width of the light-blocking bank 446 can be greater than that of the black matrix 460. The concaved curved surface of the black matrix 460 can be disposed to face the inclined side portion of the light-blocking bank 446. The ambient light L incident to the inclined side portion of the light-blocking bank 446 is lead toward the black matrix 460 and can be reflected by the black matrix 460.

The ambient light L, which is reflected by the light-blocking bank 446 and incident to the black matrix 460, can be reflected by the concaved curved surface toward the inclined side portion of the light-blocking bank 446. Namely, the ambient light L reflected by the surface of the light-blocking bank 446 and the black matrix 460 can be guided to the corresponding surface, and re-absorption and/or re-reflection can be repeated. Accordingly, the reflection of the ambient light L incident on the organic light emitting display device 400 can be minimized, and the re-absorption of the ambient light L can be maximized. As a result, in the organic light emitting display device 400, the stains caused by the reflection of the ambient light L can be minimized. Therefore, the brightness decrease of the organic light emitting display device 400 caused by the reflection of the ambient light L can be minimized, and the display quality degradation of the organic light emitting display device 400 can be minimized.

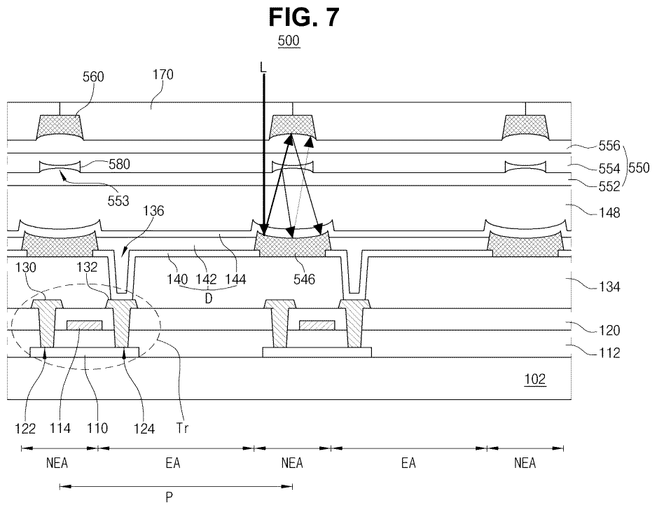

FIG. 7 is a schematic cross-section view of an organic light emitting display device according to a fifth example embodiment of the present disclosure. In comparison to the organic light emitting display device 100 of FIG. 2, the organic light emitting display device 500 of FIG. 7 further includes a touch electrode 580. The description is focused on the touch electrode 580.

Referring to FIG. 7, the touch electrode 580 can be disposed on the first inorganic insulating layer 552 of the encapsulation layer 550. The touch electrode 580 can include a plurality of electrodes. Each of the plurality of touch electrodes 580 can be disposed to correspond to a boundary of the pixel region P. Accordingly, the touch electrode 580 can be disposed to correspond to the non-emission area NEA.

The touch electrode 580 can be disposed on the first inorganic insulating layer 552 to correspond to the light-blocking bank 546. Namely, the touch electrode 580 can be disposed to overlap the light-blocking bank 546 and the black matrix 560. At least a portion of the touch electrode 580 is shielded by the black matrix 580 so that the touch electrode 580 may not be visible. Accordingly, the degradation of display quality by the touch electrode 580 can be minimized.

The touch electrode 580 can be formed of a transparent conductive material, e.g., ITO, IZO, ITZO, SnO, ZnO, ICO or AZO, but it is not limited thereto.

The organic insulating layer 554 of the encapsulation layer 550 is disposed on the touch electrode 580 to cover the touch electrode 580. The organic insulating layer 554 can act as a planarization layer. The touch electrode 580 is positioned between the first inorganic insulating layer 552 and the organic insulating layer 554. The second inorganic insulating layer 556 of the encapsulation layer 550 is disposed on the organic insulating layer 554. Accordingly, a damage to the touch electrode 580 in a process of forming the black matrix 560 and/or the color control pattern 170 can be prevented.

The first inorganic insulating layer 552 can include a convex portion 553 under the touch electrode 580. The first inorganic insulating layer 552 can include a plurality of convex portions 553, and each convex portion 553 can correspond to each touch electrode 580. The convex portion 553 is positioned between the light-blocking bank 546 and the black matrix 560. In the touch electrode 580 on the convex portion 553, a thickness of an end portion can be greater than that of a central portion. Namely, the thickness of the touch electrode 580 can be increased from a center to an end. Each of an upper surface and a lower surface of the touch electrode 580 can have a concaved curved shape.

In an example embodiment of the present disclosure, one of the upper and lower surface of the touch electrode 580 can have a concaved curved shape, and the other one of the upper and lower surface of the touch electrode 580 can have a flat shape.

The concaved curved surfaces of the touch electrode 580 faces a concaved curved surface of the light-blocking bank 546 and a concaved curved surface of the black matrix 560, respectively. The upper and lower surface of the touch electrode 580 facing the light-blocking bank 546 and the black matrix 560 can have the concaved curved shape. The concaved upper surface of the touch electrode 580 faces the concaved lower surface of the black matrix 560, and the concaved lower surface of the touch electrode 580 faces the concaved upper surface of the light-blocking bank 546.

The ambient light L incident to the light-blocking bank 546 is reflected toward the black matrix 560. The ambient light L incident to the black matrix 560 is reflected by the black matrix 560 toward the light-blocking bank 546. Namely, the ambient light L reflected by the surface of the light-blocking bank 546 and the black matrix 560 can be guided to the corresponding surface, and re-absorption and/or re-reflection can be repeated. In this instance, the reflected ambient light L can be scattered.

The scattered ambient light L can be re-absorbed and/or re-reflected onto the surface of the light shielding bank 546 and the black matrix 560 by the touch electrode 580 including an upper surface and a lower surface each having a concaved curved shape. Accordingly, the reflection of the ambient light L incident on the organic light emitting display device 500 can be minimized, and the re-absorption of the ambient light L can be maximized. As a result, in the organic light emitting display device 500, the stains caused by the reflection of the ambient light L can be minimized. Therefore, the brightness decrease of the organic light emitting display device 500 caused by the reflection of the ambient light L can be minimized, and the display quality degradation of the organic light emitting display device 500 can be minimized.

In FIG. 7, each of the upper surface of the light-blocking bank 546, the upper and lower surfaces of the touch electrode 580 and the lower surface of the black matrix 560 has a concaved curved shape. In an example embodiment, at least one of the upper surface of the light-blocking bank 546, the upper and lower surfaces of the touch electrode 580 and the lower surface of the black matrix 560 can have a flat center portion and an inclined side portion.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. An organic light emitting display device, comprising:
a substrate including an emission area and a non-emission area;
a light emitting diode corresponding to the emission area and disposed on the substrate;
a light-blocking bank corresponding to the non-emission area and disposed at a side of the light emitting diode;
an insulating layer disposed on the light emitting diode and the light-blocking bank; and
a black matrix corresponding to the non-emission area and disposed on the insulating layer,
wherein a first surface of the light-blocking bank and a first surface of the black matrix face to each other, and at least one of the first surface of the light-blocking bank and the first surface of the black matrix has a curved shape.

2. The organic light emitting display device according to claim 1, wherein at least one side surface of the light-blocking bank protrudes into the emission area beyond at least one side surface of the black matrix.

3. The organic light emitting display device according to claim 2, wherein a width of the light-blocking bank is greater than a width of the black matrix.

4. The organic light emitting display device according to claim 2, wherein a thickness of an end portion of the light-blocking bank is greater than a thickness of a center portion of the light-blocking bank, and
wherein a thickness of an end portion of the black matrix is greater than a thickness of a center portion of the black matrix.

5. The organic light emitting display device according to claim 1, wherein the light-blocking bank and the black matrix include a same material.

6. The organic light emitting display device according to claim 1, wherein the insulating layer includes a first inorganic insulating layer, an organic insulating layer and a second inorganic insulating layer, and
wherein the organic light emitting display device further comprises a touch electrode between the first inorganic insulating layer and the organic insulating layer.

7. The organic light emitting display device according to claim 6, wherein the touch electrode overlaps the light-blocking bank and the black matrix.

8. The organic light emitting display device according to claim 6, wherein the first inorganic insulating layer includes a convex portion disposed under the touch electrode.

9. The organic light emitting display device according to claim 8, wherein the convex portion of the first inorganic insulating layer overlaps the light-blocking bank and the black matrix.

10. The organic light emitting display device according to claim 8, wherein a thickness of an end portion of the touch electrode is greater than a thickness of a center portion of the touch electrode.

11. The organic light emitting display device according to claim 1, wherein the first surface of the light-blocking bank has the curved shape, and
wherein the first surface of the black matrix includes a flat portion and at least one inclined portion extending from the flat portion.

12. The organic light emitting display device according to claim 1, wherein the first surface of the black matrix has the curved shape, and
wherein the first surface of the light-blocking bank includes a flat portion and at least one inclined portion extending from the flat portion.

13. The organic light emitting display device according to claim 12, wherein the at least one inclined portion of the light-blocking bank protrudes into the emission area beyond the black matrix.

14. The organic light emitting display device according to claim 1, further comprising:
a color control pattern on the insulating layer,
wherein the color control pattern corresponds to the emission area and is alternately arranged with the black matrix.

15. An organic light emitting display device, comprising:
a substrate including an emission area and a non-emission area;
a light emitting diode corresponding to the emission area and disposed on the substrate;
a light-blocking bank corresponding to the non-emission area and disposed at a side of the light emitting diode;
an insulating layer disposed on the light emitting diode and the light-blocking bank; and
a black matrix corresponding to the non-emission area and disposed on the insulating layer,
wherein a first surface of the light-blocking bank and a first surface of the black matrix face to each other, and at least one of the first surface of the light-blocking bank and the first surface of the black matrix has a flat center portion and an inclined side portion extending from the flat center portion.

16. The organic light emitting display device according to claim 15, wherein the light-blocking bank overlaps the black matrix.

17. The organic light emitting display device according to claim 15, wherein the light-blocking bank and the black matrix include a same material.

18. The organic light emitting display device according to claim 15, wherein the insulating layer includes a first inorganic insulating layer, an organic insulating layer and a second inorganic insulating layer, and
wherein the organic light emitting display device further comprises a touch electrode between the first inorganic insulating layer and the organic insulating layer.

19. The organic light emitting display device according to claim 18, wherein a thickness of an end portion of the touch electrode is greater than a thickness of a center portion of the touch electrode.

20. The organic light emitting display device according to claim 15, further comprising:
a color control pattern on the insulating layer,
wherein the color control pattern corresponds to the emission area and is alternately arranged with the black matrix.
